(19) United States
(12) Patent Application Publication
(10) Pub. No.: US 2011/0057233 A1
(43) Pub. Date: Mar. 10, 2011

(54) Semiconductor component and method for manufacturing of the same

(75) Inventors: Ki Yeol Park, Suwon-si (KR); Jung Hee Lee, Daegu-si (KR); Ki Won Kim, Daegu-si (KR); Young Hwan Park, Seoul (KR); Woo Chul Jeon, Suwon-si (KR)

(73) Assignee: SAMSUNG ELECTRO-MECHANICS CO., LTD., Suwon (KR)

(21) Appl. No.: 12/591,409

(22) Filed: Nov. 18, 2009

(30) Foreign Application Priority Data
Sep. 8, 2009 (KR) 10-2009-0084592

(51) Int. Cl. H01L 29/778; H01L 29/772; H01L 21/335

(52) U.S. Cl. 257/194; 257/192; 438/172; 257/E29.242; 257/E29.253; 257/E21.403

(57) ABSTRACT

The present invention provides a semiconductor component. The semiconductor component in accordance with the present invention includes a lower layer including a low resistance layer and a high resistance layer with higher resistivity than the low resistance layer while surrounding a lateral surface of the low resistance layer; a source electrode disposed on a front surface of the high resistance layer; a gate structure disposed on a front surface of the low resistance layer; a drain structure disposed on a rear surface of the low resistance layer; and a base substrate surrounding the drain structure on a rear surface of the high resistance layer.

### CROSS-REFERENCE TO RELATED APPLICATIONS

This application claims the benefit of Korean Patent Application No. 10-2009-0084592 filed with the Korea Intellectual Property Office on Sep. 8, 2009, the disclosure of which is incorporated herein by reference.

### BACKGROUND OF THE INVENTION

1. Field of the Invention

The present invention relates to a semiconductor component, and, more particularly, to a semiconductor component having a nitride-based semiconductor field effect transistor structure and a method for manufacturing of the same.

2. Description of the Related Art

In general, a III-group nitride-based semiconductor containing III-group elements such as gallium (Ga), aluminum (Al), indium (In), etc. and nitrogen (N) has characteristics such as a wide energy band gap, high electron mobility and a saturated electron velocity, high thermo-chemical stability, etc. The nitride-based field effect transistor (N-FET) based on the III-group nitride-based is manufactured based a semiconductor material having the wide energy band gap, for example, materials such as gallium nitride (GaN), aluminum gallium nitride (AIGaN), indium gallium nitride (InGaN), aluminum indium gallium nitride (AIInGaN), etc.

The general nitride-based field effect transistor has a so-called high electron mobility transistor (hereinafter, referred to as ‘HEMT’) structure. For example, the semiconductor component having the HMET structure includes a base substrate, a nitride-based semiconductor layer formed on the base substrate, a source electrode and a drain electrode disposed on the semiconductor layer, and a gate electrode disposed on the semiconductor layer between the source electrode and the drain electrode. The semiconductor component can generate 2-dimensional electron gas (2DEG) used as a movement path of current in the semiconductor layer. However, since the nitride-based field effect transistor having the structure is in an ‘ON’ state in which the flow of the current is generated because resistance between the drain electrode and the source electrode is small when gate voltage is 0 or a minus value, current and power consumption are generated, thereby deteriorating high-voltage and high-current operation characteristics of the component.

### SUMMARY OF THE INVENTION

The present invention has been invented in order to overcome the above-described problems and it is, therefore, a first object of the present invention to provide a semiconductor component which can be actuated at high voltage and high current and a method for manufacturing of the same.

The present invention has been invented in order to overcome the above-described problems and it is, therefore, a second object of the present invention to provide a semiconductor component which reduces the amount of leakage current and a method for manufacturing of the same.

The present invention has been invented in order to overcome the above-described problems and it is, therefore, a third object of the present invention to provide a semiconductor component which increases the amount of current at the time of actuating a component and a method for manufacturing of the same.

In accordance with an aspect of the present invention, there is provided a semiconductor component that includes a lower layer including a low resistance layer and a high resistance layer with higher resistivity than the low resistance layer while surrounding a lateral surface of the low resistance layer; a source electrode disposed on a front surface of the high resistance layer; a gate structure disposed on a front surface of the low resistance layer; a drain structure disposed on a rear surface of the low resistance layer; and a base substrate surrounding the drain structure on a rear surface of the high resistance layer.

In accordance with the aspect of the present invention, the drain structure may include a plate unit disposed in the base substrate; and a plurality of protrusions attached to the rear surface of the low resistance layer while extending toward the low resistance layer from the plate unit.

In accordance with the aspect of the present invention, the low resistance layer may be constituted by pillars having a vertical pillar shape.

In accordance with the aspect of the present invention, the gate structure may include a gate electrode arranged to face the low resistance layer; and a field plate diffusing electric fields of the gate electrode and the source electrode while extending toward the source electrode from the gate electrode.

In accordance with the aspect of the present invention, the semiconductor component further includes an upper layer that is disposed on the lower layer and includes a wider energy band gap than the lower layer, wherein the upper layer may include a first recess portion exposing the front surface of the low resistance layer.

In accordance with the aspect of the present invention, the semiconductor component further includes an insulating layer interposed between the upper layer and the gate structure, wherein the insulating layer may conformally cover the first recess portion between the upper layer and the gate structure.

In accordance with another aspect of the present invention, there is provided a semiconductor component that includes a semiconductor layer that generates 2-dimensional electron gas (2DEG) therein and includes a low resistance layer having low resistivity at the center thereof; a source electrode including parts separated from each other on the semiconductor layer; a gate structure that is disposed on the top of the low resistance layer between the separated parts of the source electrode; and a drain structure that is disposed on the bottom of the low resistance layer, wherein the low resistance layer is used as a current path to allow current provided from 2-dimensional electron gas to flow to the drain structure when the component is actuated.

In accordance with the aspect of the present invention, the low resistance layer may provide vertical current flow orientation.

In accordance with yet another aspect of the present invention, there is provided a method for manufacturing a semiconductor component that includes preparing a preliminary base substrate; forming both a low resistance layer and a high resistance layer with higher resistivity than the low resistance layer on the preliminary base substrate; forming a source electrode on the high resistance layer; forming a gate structure on a front surface of the low resistance layer; and forming a drain structure on a rear surface of the low resistance layer.

In accordance with the aspect of the present invention, the method may further include forming an upper layer with a wider energy band gap than a lower layer on the lower layer; forming a first recess portion exposing the low resistance layer on the upper layer; and forming an insulating layer conformally covering the first recess portion.

In accordance with the aspect of the present invention, forming the gate structure may include forming a metallic layer conformally covering a resulting product where the insulating layer is formed; and forming a field plate diffusing electric fields of the gate electrode and the source electrode by removing the metallic layer in a region where the source electrode is formed.

In accordance with the aspect of the present invention, forming the low resistance layer may include forming an insulating pattern on the preliminary base substrate; and performing an epitaxial lateral over growth (ELOG) process for the preliminary base substrate with the insulating pattern.

In accordance with the aspect of the present invention, the method further includes forming a buffer layer on the preliminary base substrate before forming the insulating pattern, wherein the forming the insulating pattern may include forming a plurality of insulating protrusions protruded from the buffer layer on the buffer layer.

In accordance with the aspect of the present invention, forming the drain structure may include forming a second recess portion exposing the insulating pattern to a region of the preliminary base substrate facing the low resistance layer; and forming a third recess portion exposing a rear surface of the low resistance layer on the lower layer.

In accordance with the present invention, a semiconductor component include a gate structure and a drain structure that are separated from each other with a low resistance layer and a high resistance layer surrounding the low resistance layer to have a structure to provide a vertical current flow. Therefore, the present invention allows current to flow using the low resistance layer having low resistivity to thereby increase the amount of current at the time of actuating the component.

In accordance with the present invention, the semiconductor component can reduce leakage current in the component by providing the high resistance layer having comparatively high resistivity on an area of a base substrate other than an area where the low resistance layer is formed.

In accordance with the preset invention, by forming an insulating layer between the low resistance layer and the gate structure, when voltage is not applied to the gate structure, the semiconductor component may be in a normally off state in which no current flows even by applying the voltage to the drain structure. Accordingly, the present invention can provide a semiconductor component having a high electron mobility transistor (HEMT) structure which can perform an enhancement mode operation.

In the semiconductor component in accordance with the present invention, the gate structure is provided to perform a field plating function to diffuse an electric filed of the gate electrode and the source electrode to provide a semiconductor component which can be actuated at high voltage.

A method for manufacturing a semiconductor component in accordance with the present invention can manufacture a semiconductor component which can be actuated at high voltage and high current by allowing current to flow through the low resistance layer having comparatively low resistivity and providing the area other than the low resistance layer as the high resistance layer.

The method for manufacturing a semiconductor component in accordance with the present invention can manufacture the semiconductor component which can be actuated at high voltage by allowing the gate structure to perform a field plating function to diffuse the electric filed of the gate electrode and the source electrode.

### BRIEF DESCRIPTION OF THE DRAWINGS

These and/or other aspects and advantages of the present general inventive concept will become apparent and more readily appreciated from the following description of the embodiments, taken in conjunction with the accompanying drawings of which:

FIG. 1 is a diagram showing a semiconductor component in accordance with an embodiment of the present invention;

FIG. 2 is a diagram for explaining the flow of current when a semiconductor component shown in FIG. 1 is actuated; and

FIGS. 3 to 7 are diagrams for explaining a process of manufacturing a semiconductor component in accordance with an embodiment of the present invention.

### DETAILED DESCRIPTION OF THE PREFERABLE EMBODIMENTS

Advantages and characteristics of the present invention, and a method for achieving them will be apparent with reference to embodiments described below in addition to the accompanying drawings. However, the present invention is not limited to the embodiments disclosed below, but may be implemented in various forms. The embodiments may be provided to completely disclose the present invention and allow those skilled in the art to completely know the scope of the present invention. Throughout the specification, like elements refer to like reference numerals.

Terms used in the specification are used to explain the embodiments and not to limit the present invention. In the specification, a single type includes even a plural type as long as not particularly mentioned. ‘comprise’ and/or ‘comprising’ used the specification mentioned constituent members, steps, operations and/or elements do not exclude existence or addition of one or more other constituent members, steps, operations and/or elements.

Further, the embodiments described in the specification will be described with reference to cross-sectional views and/or plan views which are ideal exemplary diagrams of the present invention. In the drawings, the thicknesses of layers and regions are extended in order to effectively describe technical contents. Therefore, a form of the exemplary diagram may be modified by a manufacturing method and/or tolerance. Accordingly, the embodiments of the present invention are not limited to a specific form but include a change of a form generated in accordance with a manufacturing process. For example, a right-angle etching region may have a round shape or a shape having predetermined curvature. As a result, regions illustrated in the figures have schematic attributes and shapes of the regions illustrated in the figures are used for illustrating a specific form of a component region and not for limit the scope of the present invention.

Hereinafter, a semiconductor component and a method for manufacturing of the same in accordance with an embodiment of the present invention will be described in detail with reference to the accompanying drawings.

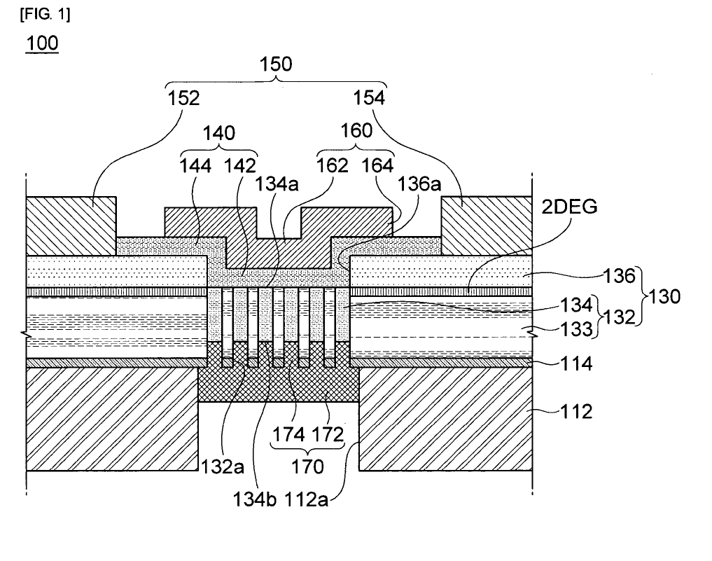

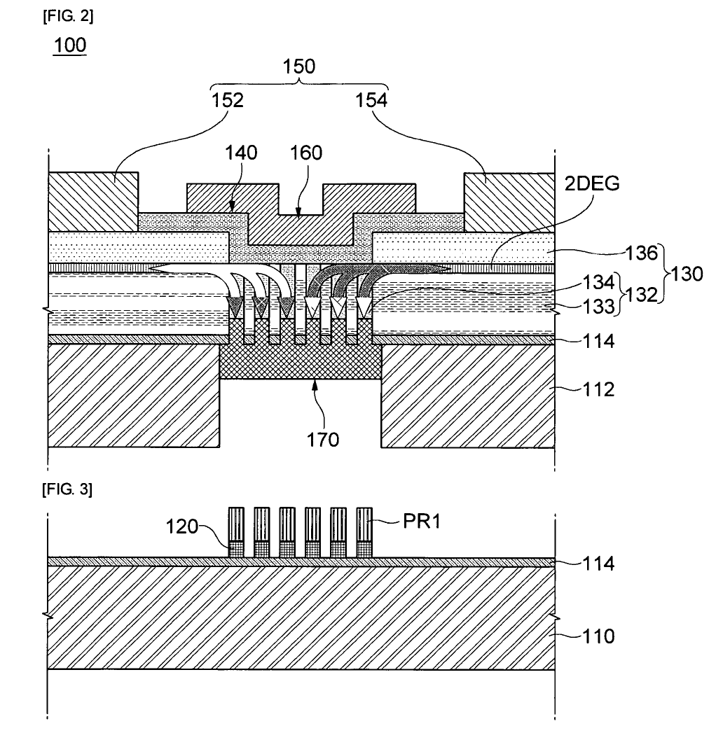

FIG. 1 is a diagram showing a semiconductor component in accordance with an embodiment of the present invention and FIG. 2 is a diagram explaining the flow of current when a semiconductor component shown in FIG. 1 is actuated.

Referring to FIG. 1, the semiconductor component 100 in accordance with the embodiment of the present invention may include a base substrate 112, a semiconductor layer 130, a source structure 150, a gate structure 160, and a drain structure 170.

The base substrate 112 may be a plate for forming a semiconductor component having an HEMT (high electron mobility transistor) structure. For example, the base substrate 112 may be a semiconductor substrate. As one example, the base substrate 112 may be at least one of a silicon substrate, a silicon carbide substrate, and a sapphire substrate.

The semiconductor layer 130 may be disposed on the base substrate 112. As one example, the semiconductor layer 130 may include a lower layer 132 and an upper layer 136 that are sequentially laminated on the base substrate 112. The upper layer 136 may be made of a material having a wider energy band gap than the lower layer 132. In addition, the upper layer 136 may be made of a material having a lattice constant different from the lower layer 132. For example, the lower layer 132 and the upper layer 136 may be a layer containing a III-group nitride-based material. More specifically, the lower layer 132 and the upper layer 136 may be made of any one selected from gallium nitride (GaN), aluminum gallium nitride (AIGaN), indium gallium nitride (InGaN), and indium aluminum gallium nitride (InAlGaN). As one example, the lower layer 132 may be a gallium nitride layer and the upper layer 136 may be an aluminum gallium nitride layer. In the semiconductor layer 130 having the above-mentioned structure, 2-dimensional electron gas (2DEG) may be generated on an interface between the lower layer 132 and the upper layer 136. Current may flow through the 2-dimensional electron gas (2DEG) when the semiconductor component 100 is actuated. Meanwhile, a buffer layer 114 may be provided between the base substrate 112 and the lower layer 132. The buffer layer 114 may be a layer for solving problems caused due to a lattice mismatch between the base substrate 112 and the lower layer 132.

The lower layer 132 may include a high resistance layer 133 and a low resistance layer 134. The high resistance layer 133 may have higher resistivity than the low resistance layer 134 and the low resistance layer 134 may have lower resistivity than the high resistance layer 133. The high resistance layer 133 may be disposed to surround a lateral surface of the low resistance layer 134. The low resistance layer 134 may be constituted by a plurality of pillars having an island-shape cross section in the lower layer 132. The low resistance layer 134 may be formed by a predetermined growth process using the base substrate 112 or the buffer layer 114 as a seed layer. For example, the low resistance layer 134 may be formed by performing an epitaxial lateral over growth (ELOG) process and a detailed description thereof will be described below.

An insulating layer 140 may be disposed on the upper layer 136 of the semiconductor layer 130. The insulating layer 140 may be constituted by a first part 142 attached to the low resistance layer 134 of the lower layer 132 and a second part 144 attached to the upper layer 136. A first recess portion 136a to expose the low resistance layer 134 of the lower layer 132 may be formed on the upper layer 136 so as to directly attach the first part 142 of the insulating layer 140 to the low resistance layer 134. Meanwhile, the insulating layer 140 may be any one of a silicon oxide layer (SiO), a silicon nitride layer (SiN), and a silicon oxide nitride layer (SiON).

The source structure 150 may be attached to the semiconductor layer 130 outside of the insulating layer 140. The source structure 150 may have parts that are apart from each other with the gate structure 160 interposed therebetween. The source structure 150 is attached to the upper layer 136 of the semiconductor layer 130 to form an ohmic contact.

The gate structure 160 may be disposed on the insulating layer 140. The gate structure 160 may be constituted by a gate electrode 162 disposed at a recessed portion of the insulating layer 140 by the first recess portion 136a and a field plate 164 extending toward the source electrode 150 from the gate electrode 162. The gate structure 160 is attached to the insulating layer 140 to form a schottky contact. Therefore, the gate structure 160 may be used as the gate electrode. In addition, the field plate 164 may perform a field plating function to diffuse electric fields of the gate structure 160 and the source electrode 150.

The drain structure 170 may be attached to a rear surface 134b of the low resistance layer 134. As one example, the drain structure 170 may include a plate unit 172 and a plurality of protrusions 174 protruded from the plate unit 172. The plate unit 172 may be disposed in the base substrate 112. For this, a second recess portion 112a to expose the lower layer 132 is formed in the base substrate 112 and the plate unit 172 may be disposed in the second recess portion 112a. The protrusions 174 each have a pillar shape protruding toward the low resistance layer 134 from the plate unit 172. Therefore, the protrusions 174 each may have the island-shape cross section. The protrusions 174 may be attached to the low resistance layer 134 in the lower layer 132. For this, the third recess portion 132a may be formed in the lower layer 132. Herein, the third recess portion 132a may have a shape corresponding to the protrusions 174.

Referring to FIG. 2, the semiconductor component 100 in accordance with the embodiment of the present invention may include the gate structure 160 and the drain structure 170 that are vertically separated from each other with the low resistance layer 134 interposed therebetween. As a result, when voltage is applied to the gate structure 160 at the time of actuating the semiconductor component 100, current passing through the 2-dimensional electron gas (2DEG) is collected into the low resistance layer 134 and thereafter, flows to the drain structure 170. Therefore, after the semiconductor component 100 may have a structure to allow the current to flow to the drain structure 170 through the low resistance layer 134 after providing the current to the low resistance layer 134 having comparatively low resistivity. Accordingly, the present invention can implement a semiconductor component which can be actuated at high current by increasing the amount of current of the semiconductor component 100.

As described above, the semiconductor component 100 may include the gate structure 160 disposed on a front surface 134a of the low resistance layer 134, a drain structure 170 disposed on the rear surface 134b of the low resistance layer 134, and the high resistance layer 133 surrounding the low resistance layer 134. When the semiconductor component 100 having the structure is actuated, the current flows from the 2-dimenional electron gas (2DEG) to the low resistance layer 134 and thereafter, the current may vertically flow primarily to the drain structure 170 through the low resistance layer 134 having low resistivity. As a result, the semiconductor component 100 increases the amount of current of the component by allowing the current to flow from the 2-dimenional electron gas (2DEG) to the drain structure 170 through the low resistance layer 134 having comparatively high crystallity, such that the semiconductor component can be actuated at high current. In addition, it is possible to prevent the current from leaking through the semiconductor layer 130 by providing the high resistance layer 133 having comparatively high resistivity in an area of the base substrate 112 other than an area where the low resistance layer 134 is formed.

By forming the insulating layer 140 between the low resistance layer 134 and the gate structure 160, when voltage is not applied to the gate structure 160, the semiconductor component 100 may be in a normally off state in which not current flows even by applying the voltage to the source electrode 150 and the drain structure 170. Accordingly, the semiconductor component 100 has a high electron mobility transistor (HEMT) structure which can perform an enhancement mode operation.

Further, the semiconductor component 100 may include the gate structure 160 including the gate electrode 172 and the field plate 164 extending toward the source electrode 150 from the gate electrode 172. Accordingly, since the electric fields of the gate electrode 160 and the source electrode 150 can be diffused by the gate structure 160, the semiconductor component 100 may be actuated at high voltage.

Hereinafter, a method for manufacturing a semiconductor component in accordance with an embodiment of the present invention will be described in detail with reference to the accompanying drawings. Herein, duplicate contents with the contents of the semiconductor component described above or simplified.

FIGS. 3 to 7 are diagrams for explaining a process of manufacturing a semiconductor component in accordance with the present invention. Referring to FIG. 3, a preliminary base substrate 110 can be prepared. For example, a semiconductor substrate can be prepared. The base substrate 110 may use at least one of a silicon substrate, a silicon carbide substrate, and a sapphire substrate.

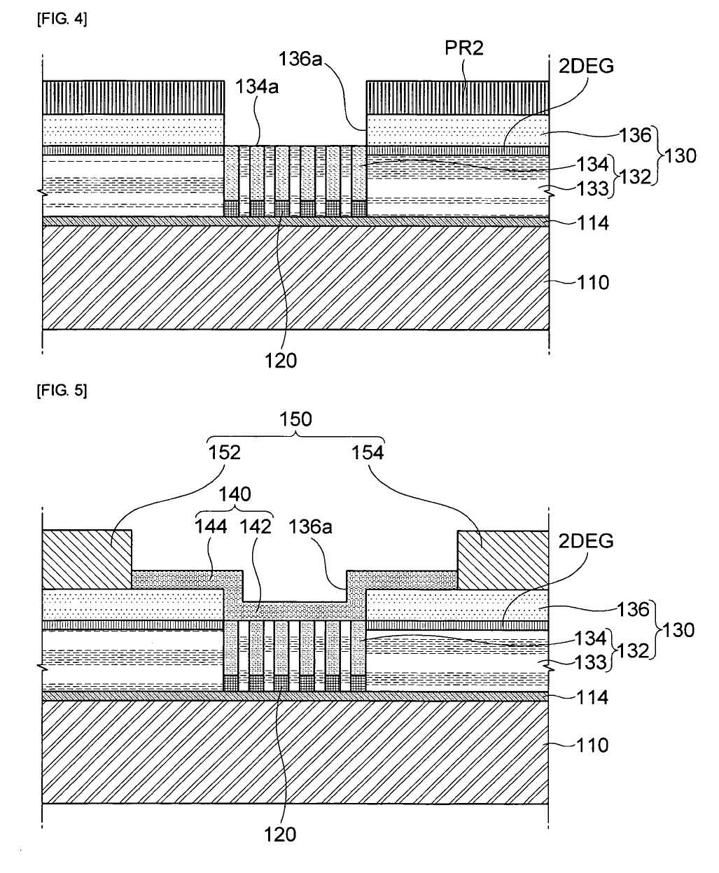

A buffer layer 114 may be formed on the preliminary base substrate 110. The buffer layer 114 may be used to solve problems caused due to a lattice mismatch between the semiconductor layer 130 (see FIG. 4) formed on the preliminary base substrate 110 and the preliminary base substrate 110.

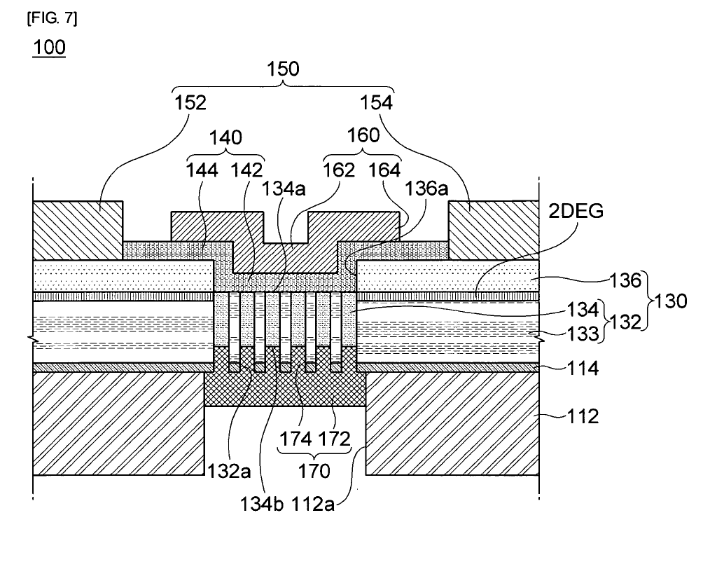

An insulating pattern 120 may be formed on the buffer layer 114. A step of forming the insulating pattern 120 may include a step of forming an insulating layer conformally on the buffer layer 114 and a step of performing a first etching process of etching the insulating layer by using a first photoresist pattern PR1. The insulating layer may be any one of a silicon nitride layer(SiN) and a silicon oxide layer (SiO). As a result, the insulating pattern 120 that is made of the silicon nitride layer (SiN) or the silicon oxide layer (SiO) and constituted by a plurality of protrusions protruded from the buffer layer 114 may be formed on the buffer layer 114. Herein, since the insulating patter 120 can define the shapes of the protrusions 174 (see FIG. 7) of the drain structure 170 (see FIG. 7), the shape of the insulating pattern 120 may be adjusted by considering the shapes of the protrusions 174.

Referring to FIG. 4, the semiconductor layer 130 may be formed. For example, a lower layer 132 may be formed on the preliminary base substrate 110 with the insulating pattern 120. As one example, the lower layer 132 may be formed by performing an epitaxial lateral over growth (ELOG) process. The epitaxial lateral over growth process may be a process to grow the lower layer 132 on the buffer layer 114 by using the preliminary base substrate 112 or the buffer layer 114 as a seed layer. Herein, a part that grows on the buffer layer 114 and a part that grows on the insulating pattern 120 may have different from each other in crystallity and crystallic orientation. For example, the part that grows on the insulating pattern 120 may have higher crystallity than the part that grows on the buffer layer 114. Further, the part that grows on the insulating pattern 120 may have a substantially horizontal crystallic orientation and the part that grows on the buffer layer 114 may have a substantially vertical orientation. The grow area having high crystallity may have lower resistivity than the growth area having low crystallity. A lower layer having comparatively low resistivity may be used as a low resistance layer 134 and another lower layer having comparatively high resistivity may be used as a high resistance layer 133. Herein, the low resistance layer 134 may be used as a path through which current flows when the component is actuated.

An upper layer 136 may be formed on a resulting product where the lower layer 132 is formed. As one example, the step of forming the upper layer 136 may include a step of forming a semiconductor layer having a wider energy band gap than the lower layer 132 by performing the epitaxial growth process using the lower layer 132 as the seed layer. As another example, the step of forming the upper layer 136 may include a step of forming the semiconductor layer having the wider energy band gap than the lower layer 132 by performing a chemical or physical vapor deposition process for a semiconductor layer having an energy band gap with respect to the resulting product where the lower layer 132 is formed. In addition, a first recess portion 136a for exposing the low resistance layer 134 may be formed on the upper layer 136. For example, by performing an etching process using a second photoresist pattern PR2 as an etching mask on a semiconductor layer, a trench for exposing a front surface 134a of the low resistance layer 134 may be formed on the semiconductor layer. As a result, the upper layer 136 having the first recess portion 136a to expose the low resistance layer 134 may be formed on the lower layer 132.

Meanwhile, the lower layer 132 may be a layer_made of gallium nitride (GaN) and the upper layer 136 may be a layer made of aluminum gallium nitride (AIGaN). Therefore, 2-dimensional electron gas (2DEG) may be formed on an interface between the lower layer 132 and the upper layer 136 and current may flow through the 2-dimensional electron gas (2DEG). Further, the lower layer 132 may be constituted by the low resistance layer 134 made of gallium nitride having high crystallity and the high resistance layer 133 made of gallium nitride having comparatively low crystallity.

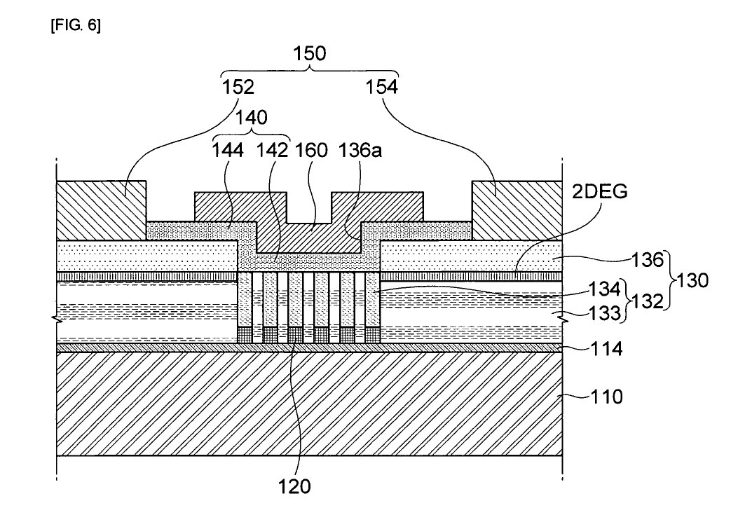

Referring to FIG. 6, an insulating layer 140 may be formed. For example, a step of forming the insulating layer 140 may include a step of forming a predetermined dielectric layer conformally on a resulting product where the upper layer 136 is formed and removing the dielectric layer portion on the high resistance layer 133. Therefore, the insulating layer 140 may be constituted by a first part 142 attached to the low resistance layer 134 exposed through the first recess portion 136a of the upper layer 136 and a second part 144 attached to the upper layer 136.

A source electrode 150 may be formed. The source electrode 150 may be attached directly to the upper layer 136 of the semiconductor layer 130 on the top of the high resistance layer 133. Therefore, the source electrode 150 may include a first electrode section 152 disposed at one side and a second electrode section 154 disposed at the other side on the basis of the low resistance layer 134. Herein, the first and second electrode sections 152 and 154 are electrically connected to each other to operate as one source electrode 150.

Referring to FIG. 6, a gate structure 160 may be formed on the insulating layer 140. A step of forming the gate structure 160 may include a step of forming a metallic layer conformally covering a resulting product where the insulating layer 140 is formed and a step of removing a metallic layer of a region other than a central region on the insulating layer 140. Therefore, the gate structure 160 may be constituted by a gate electrode 162 disposed on the insulating layer 140 recessed by the first recess portion 136a of the upper layer 136 and a field plate 164 extending toward the source electrode 150 from the gate electrode 162.

Referring to FIG. 7, a base substrate 112 may be formed. For example, by performing a predetermined photoresist etching process for the preliminary base substrate 110 (see FIG. 7), a trench for exposing a rear surface 134b of the low resistance layer 134 may be formed on the semiconductor layer 130. Therefore, a recess portion 112a formed at a region facing the low resistance layer 134 is formed on the base substrate 112 and a plurality of third recess portions 132a having a pillar shape, which expose the rear surface 134b of the low resistance layer 134 are formed on the lower layer 132 of the semiconductor layer 130. The insulating pattern 120 and the buffer layer 114 of a region corresponding to the insulating pattern 120 may be removed by the etching process.

In addition, a drain structure 170 may be formed, which covers the second recess portion 112a and the third recess portion 132a. The step of forming the drain structure 170 may include forming a metallic layer burying the second recess portion 112a and the third recession portion 132a. Therefore, the drain structure 170 may be formed, which is constituted by the plate unit 172 having a plate shape in the second recess portion 112a and the plurality of protrusions 174 protruded toward the low resistance layer 134 from the plate unit 172. The drain structure 170 having the structure may be used as a drain electrode by ohmic-contacting the protrusions 174 to the low resistance layer 134.

The above detailed description exemplifies the present invention. Further, the above contents just illustrate and describe preferred embodiments of the present invention and the present invention can be used under various combinations, changes, and environments. That is, it will be appreciated by those skilled in the art that substitutions, modifications and changes may be made in these embodiments without departing from the principles and spirit of the general inventive concept, the scope of which is defined in the appended claims and their equivalents. The above-mentioned embodiments are used to describe a best mode in implementing the present invention. The present invention can be implemented in a mode other than a mode known to the art by using another invention and various modifications required a detailed application field and usage of the present invention can be made. Therefore, the detailed description of the present invention does not intend to limit the present invention to the disclosed embodiments. Further, the appended claims should be appreciated as a step including even another embodiment.

What is claimed is:

1. A semiconductor component, comprising:
a lower layer including a low resistance layer and a high resistance layer with higher resistivity in comparison with the low resistance layer, and the high resistance layer surrounding a lateral surface of the low resistance layer;
a source electrode disposed on a front surface of the high resistance layer;
a gate structure disposed on a front surface of the low resistance layer;
a drain structure disposed on a rear surface of the low resistance layer; and
a base substrate surrounding the drain structure on a rear surface of the high resistance layer.

2. The semiconductor component of claim 1, wherein the drain structure includes:
a plate unit disposed in the base substrate; and
a plurality of protrusions attached to the rear surface of the low resistance layer while extending toward the low resistance layer from the plate unit.

3. The semiconductor component of claim 1, wherein the low resistance layer is constituted by pillars having a vertical pillar shape.

4. The semiconductor component of claim 1, wherein the gate structure includes:
a gate electrode arranged to face the low resistance layer; and
a field plate diffusing electric fields of the gate electrode and the source electrode while extending toward the source electrode from the gate electrode.

5. The semiconductor component of claim 1, further comprising:
an upper layer that is disposed on the lower layer and includes a wider energy band gap in comparison with the lower layer,
wherein the upper layer includes a first recess portion to expose the front surface of the low resistance layer.

6. The semiconductor component of claim 5, further comprising:
an insulating layer interposed between the upper layer and the gate structure,
wherein the insulating layer conformally covers the first recess portion between the upper layer and the gate structure.

7. A semiconductor component, comprising:
a semiconductor layer that generates 2-dimensional electron gas (2DEG) therein and includes a low resistance layer having low resistivity at the center thereof;
a source electrode including parts apart from each other on the semiconductor layer;
a gate structure that is disposed on the top of the low resistance layer between the apart from parts of the source electrode; and
a drain structure disposed on the bottom of the low resistance layer,
wherein the low resistance layer is used as a current path to allow current provided from 2-dimensional electron gas to the drain structure when the component is actuated.

8. The semiconductor component of claim 7, wherein the low resistance layer provides vertical current flow orientation.

9. A method for manufacturing a semiconductor component, comprising:
preparing a preliminary base substrate;
forming both a low resistance layer and a high resistance layer with higher resistivity in comparison with the low resistance layer on the preliminary base substrate;
forming a source electrode on the high resistance layer;
forming a gate structure on a front surface of the low resistance layer; and
forming a drain structure on a rear surface of the low resistance layer.

10. The method for manufacturing a semiconductor component of claim 9, further comprising:
forming an upper layer with a wider energy band gap in comparison with a lower layer on the lower layer;
forming a first recess portion to expose the low resistance layer on the upper layer; and
forming an insulating layer to cover the first recess portion conformally.

11. The method for manufacturing a semiconductor component of claim 10, wherein forming the gate structure includes:
forming a metallic layer to cover a resulting product conformally where the insulating layer is formed; and
forming a field plate diffusing electric fields of the gate electrode and the source electrode by removing the metallic layer in a region where the source electrode is formed.

12. The method for manufacturing a semiconductor component of claim 9, wherein forming the low resistance layer includes:
forming an insulating pattern on the preliminary base substrate; and
performing an epitaxial lateral over growth (ELOG) process with respect to the preliminary base substrate where the insulating pattern is formed.

13. The method for manufacturing a semiconductor component of claim 12, further comprising:
forming a buffer layer on the preliminary base substrate before forming the insulating pattern.
wherein the forming the insulating pattern includes forming a plurality of insulating protrusions protruded from the buffer layer on the buffer layer.

14. The method for manufacturing a semiconductor component of claim 12, wherein forming the drain structure includes:
forming a second recess portion to expose the insulating pattern to a region of the preliminary base substrate facing the low resistance layer; and
forming a third recess portion to expose a rear surface of the low resistance layer on the lower layer.
